(19) United States
(12) Patent Application Publication
(10) Pub. No.: US 2023/0074269 A1
(43) Pub. Date: Mar. 9, 2023

(54) TECHNOLOGIES FOR APPLYING GOLD-PLATED CONTACT PADS TO CIRCUIT BOARDS

(71) Applicant: Intel Corporation, Santa Clara, CA (US)

(72) Inventors: Donald Tiendung Tran, Phoenix, AZ (US); Srikant Nekkanty, Chandler, AZ (US)

(73) Assignee: Intel Corporation, Santa Clara, CA (US)

(21) Appl. No.: 17/469,449

(22) Filed: Sep. 8, 2021

(51) Int. Cl. H05K 3/40; H05K 1/18

(52) U.S. Cl. CPC H05K 3/4015; H05K 1/181; H05K 2201/09409; H05K 2201/10325; H05K 2201/0338

(57) ABSTRACT

Technologies for applying gold-plated contact pads to circuit boards are disclosed. In one embodiment, an array of gold-plated contact pads is prepared on a flexible substrate. The array of gold-plated contact pads can then be transferred to a circuit board, such as by soldering the gold-plated contact pads to the circuit board. In another embodiment, an array of contact pads are prepared on a top and bottom surface of a substrate, and vias are added to connect the contact pads on the top and bottom surfaces. The top array of contact pads are gold-plated. The bottom array of contact pads are mated to a circuit board. Techniques described herein allow for gold-plated contact pads to be applied to a circuit board without requiring the entire circuit board to undergo a gold plating process, which may reduce manufacturing costs.

### BACKGROUND

Circuit boards may be manufactured with contact pads for mating with integrated circuit components, such as a processor. For example, a socket may be mated with a circuit board, and a processor can then mate with the socket. In some cases, the socket may be soldered to the circuit board. In other cases, the socket may interface with the circuit board compression mounted to contact pads on the circuit board. Such contact pads may be gold-plated in order to reduce corrosion of the contact pads and increase the quality of the electrical connection. A socket connected by solder may induce stress to the circuit board, cause warpage, or risk a solder joint failing. However, gold plating contact pads directly on the entire circuit board may increase the manufacturing cost of the circuit board.

### BRIEF DESCRIPTION OF THE DRAWINGS

FIG. 1 is an isometric view of a pad carrier supporting an array of gold-plated contact pads on a substrate.

FIG. 2 is a cross-sectional side view of the pad carrier of FIG. 1.

FIG. 3 is an isometric view of the pad carrier of FIG. 1 above a circuit board.

FIG. 4 is a cross-sectional side view of the pad carrier and circuit board of FIG. 3.

FIG. 5 is a cross-sectional side view of the pad carrier and circuit board of FIG. 3.

FIG. 6 is a cross-sectional side view of the circuit board of FIG. 3 with the array of gold-plated contact pads.

FIG. 7 is an isometric view of the circuit board of FIG. 3 with the array of contact pads.

FIG. 8 is an isometric view of the circuit board of FIG. 3 with a socket and an integrated circuit component above the socket.

FIG. 9 is a cross-sectional side view of the circuit board and integrated circuit component of FIG. 8.

FIG. 10 is an isometric view of the circuit board of FIG. 8 with the integrated circuit component mated with the socket.

FIG. 11 is a cross-sectional side view of the circuit board and integrated circuit component of FIG. 10.

FIG. 12 is an isometric view of a substrate supporting copper planes.

FIG. 13 is a cross-sectional side view of the substrate of FIG. 12.

FIG. 14 is a cross-sectional side view of the substrate of FIG. 12 after patterning of contact pads

FIG. 15 is a cross-sectional side view of the substrate of FIG. 12 with vias connecting contact pads.

FIG. 16 is a cross-sectional side view of the substrate of FIG. 12 with gold-plated contact pads.

FIG. 17 is an isometric view of a circuit board with the substrate of FIG. 12 above the circuit board.

FIG. 18 is a cross-sectional side view of the circuit board and substrate of FIG. 17.

FIG. 19 is a cross-sectional side view of the circuit board of FIG. 17 with the substrate mated with the circuit board.

FIG. 20 is an isometric view of the circuit board and substrate of FIG. 19.

FIG. 21 is a top view of a wafer and dies that may be included in a microelectronic assembly, in accordance with any of the embodiments disclosed herein.

FIG. 22 is a cross-sectional side view of an integrated circuit device that may be included in a microelectronic assembly, in accordance with any of the embodiments disclosed herein.

FIGS. 23A-23D are perspective views of example planar, gate-all-around, and stacked gate-all-around transistors.

FIG. 24 is a cross-sectional side view of an integrated circuit device assembly that may include a microelectronic assembly, in accordance with any of the embodiments disclosed herein.

FIG. 25 is a block diagram of an example electrical device that may include a microelectronic assembly, in accordance with any of the embodiments disclosed herein.

### DETAILED DESCRIPTION

In various embodiments disclosed herein, gold-plated contact pads can be transferred to a circuit board, allowing an integrated circuit component to be pressure mounted on the circuit board. In one embodiment, gold-plated contact pads are formed on one side of a substrate. The contact pads are soldered to the circuit board, and the substrate is removed. In another embodiment, an array of contact pads are formed on a top side of a substrate, and an array of contact pads are formed on a bottom side of the substrate. A via connects the contact pads on the top side to contact pads on the bottom side. The substrate is then soldered to the circuit board.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

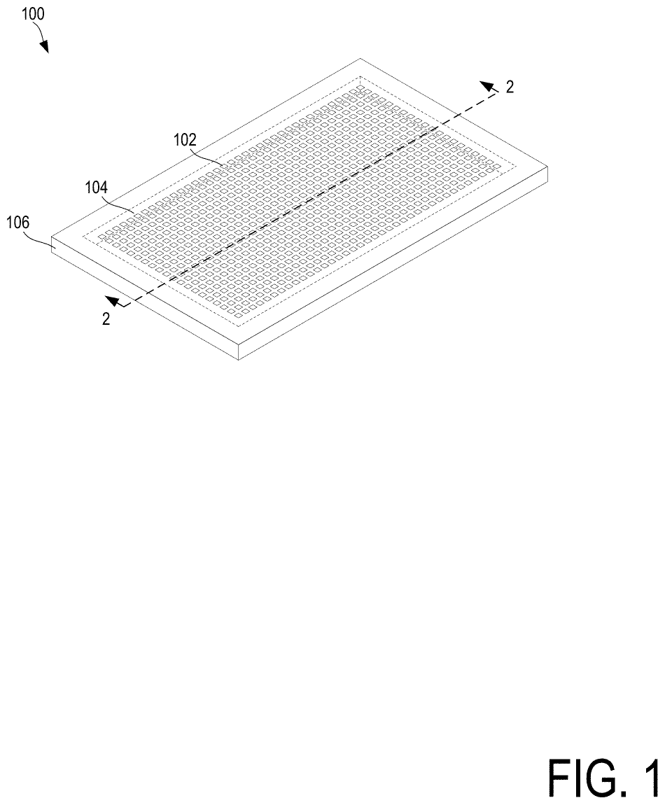

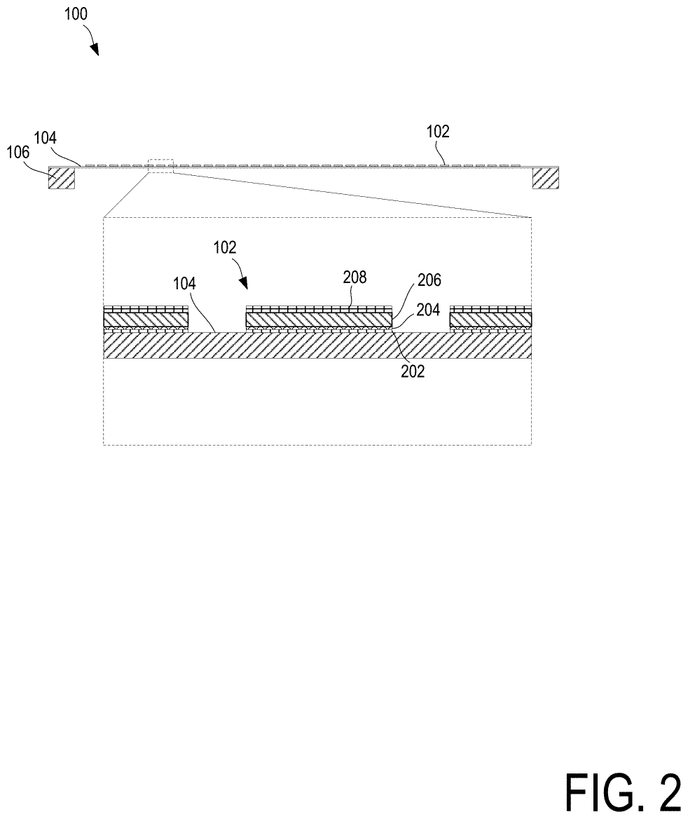

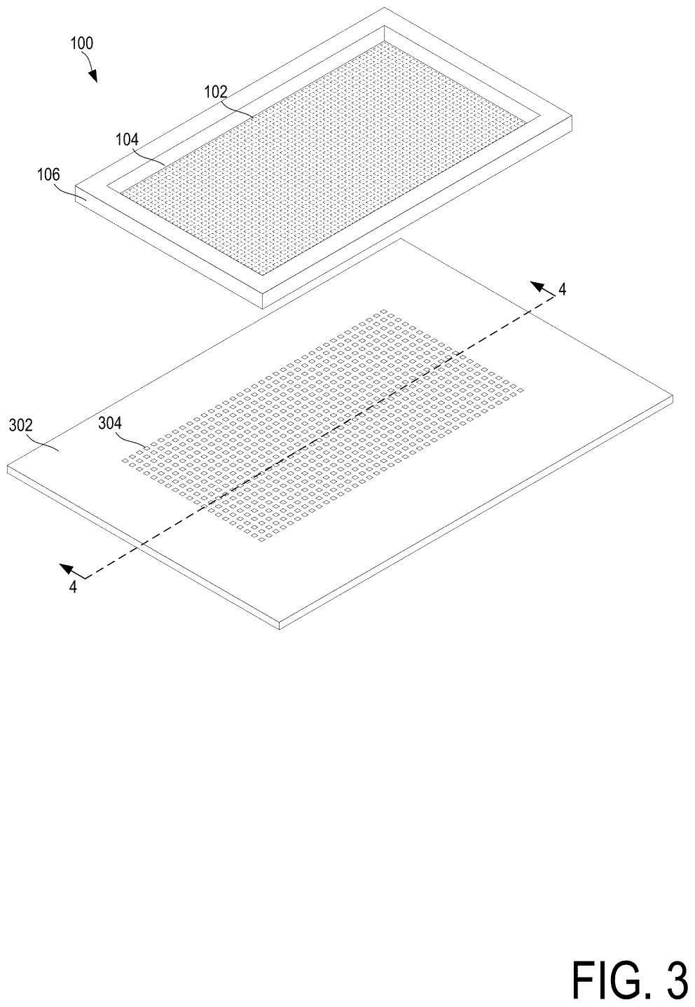

Referring now to FIG. 1, in one embodiment, a pad carrier 100 has an array of gold-plated contact pads 102. The contact pads 102 adhere to a substrate 104, which is stretched over a frame 106. A cross-sectional view of the pad carrier 100 is shown in FIG. 2. As discussed below in more detail in regard to FIGS. 3-7, the contact pads 102 of the pad carrier 100 are to be transferred to a circuit board.

Each contact pad 102 may have any suitable dimensions, such as a width and/or length of 0.2-2 millimeters. The contact pads 102 may have any suitable pitch, such as 0.4-2.5 millimeters. Each contact pad 102 may have any suitable height, such as 10-100 micrometers. The pad carrier 100 may include any suitable number of contact pads 102, such as 100-20,000 contact pads 102. Each contact pad 102 may have any suitable shape, such as a circle, rectangle, parallelogram, etc. The array of contact pads 102 may have one or more areas where no or fewer contact pads 102 are present, such as an interior rectangular area with no contact pads 102. The array of contact pads 102 may have any suitable width or length, such as 5-250 millimeters.

In the illustrative embodiment, each contact pad 102 adheres to the substrate 104 with an adhesive layer 202. A gold plate layer 204 is adjacent the adhesive layer 202. A nickel-plated copper layer 206 is adjacent the gold plate layer 204, and a tin plate layer 208 is adjacent the copper layer 206.

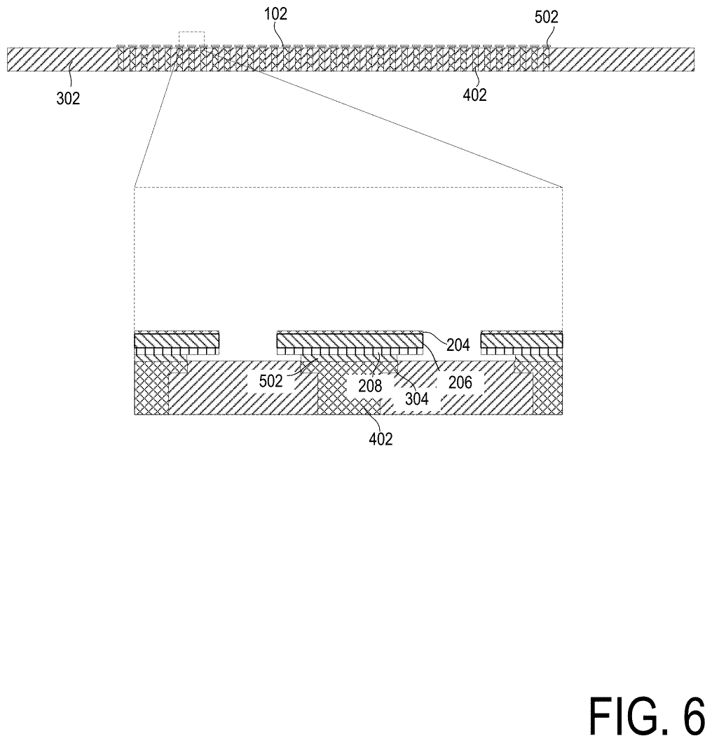

In the illustrative embodiment, the adhesive layer 202 will stick to the substrate 104 when the substrate 104 is peeled away, leaving the gold plate layer 204 exposed (see FIG. 6). The adhesive layer 202 may be any suitable material that will keep the contact pad 102 in place relative to the substrate 104 but can be removed without damaging the contact pad 102 or other component. In some embodiments, the adhesive layer 202 may be chemically removed.

The gold plate layer 204 may be any suitable thickness. In the illustrative embodiment, the gold plate layer 204 is about 375 nanometers thick. In other embodiments, the gold plate layer 204 may be, e.g., 250-2,000 nanometers thick. The gold plate layer 204 may be added by, e.g., electroless nickel immersion gold plating, electrolytic gold plating, etc.

The copper layer 206 may be any suitable thickness, such as 5-100 micrometers. In the illustrative embodiment, the copper layer 206 is plated in nickel. In other embodiments, the copper layer 206 may not have any coating or may have a different coating. For example, the copper layer 206 may have a layer of organic solderability preservative (OSP) placed instead of the tin plate layer 208. The tin plate layer 208 may be any suitable thickness, such as 5-50 micrometers.

In the illustrative embodiment, the substrate 104 is a flexible substrate, such as a polyimide film (e.g., Kapton® polyimide film). In other embodiments, the substrate 104 may be rigid or semi-flexible. The illustrative flexible substrate 104 is stretched over a frame 106, which holds the substrate 104 and contact pads 102 in place. The frame 106 may be made from any suitable material that can hold the substrate 104 in place, such as plastic, metal, wood, etc.

The contact pads 102 may be created on the substrate 104 in any suitable manner. In the illustrative embodiment, the contact pads 102 may be made using flexible printed circuitry manufacturing techniques. The contact pads 102 may be made using any suitable combination of techniques, such as, e.g., chemical vapor deposition, atomic layer deposition, physical layer deposition, molecular beam epitaxy, layer transfer, photolithography, dry etching, wet etching, thermal treatments, flip chip, layer transfer, magnetron sputter deposition, pulsed laser deposition, cold spray, etc.

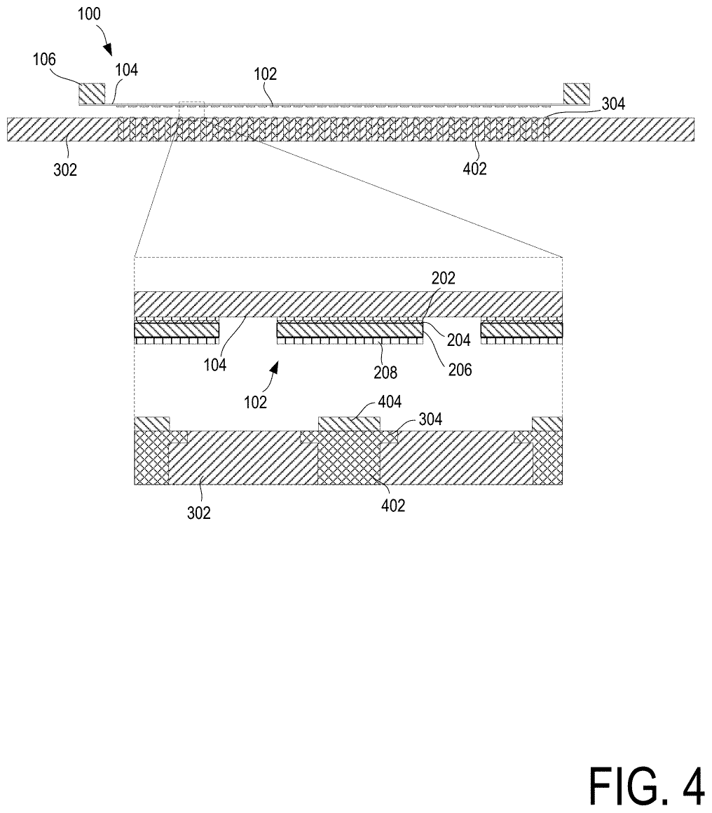

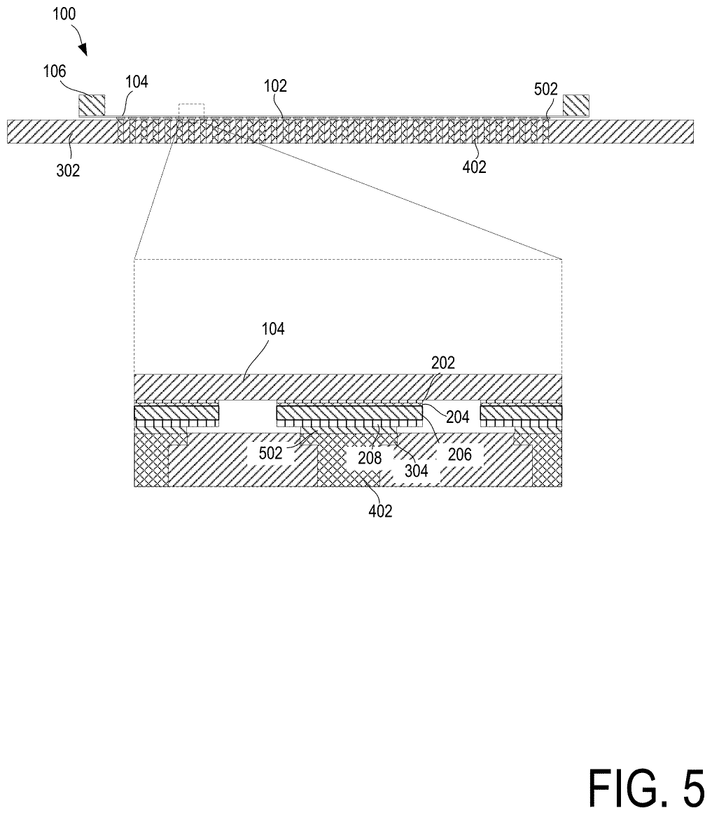

Referring now to FIG. 3, in one embodiment, a circuit board 302 is positioned below the pad carrier 100 (with contact pads 102 facing the circuit board 302). A cross-sectional side view of the circuit board 302 and pad carrier 100 is shown in FIG. 4. The pad carrier 100 will mate with the circuit board 302, and the contact pads 102 will be transferred to the top side of circuit board 302, as described in more detail below in regard to FIGS. 5-7. It should be appreciated that, as used herein, the “top side,” “bottom side,” etc., of the circuit board 302 is an arbitrary designation used for clarity and does not denote a particular required orientation for manufacture or use. Although the illustrative embodiment described has the contact pads 102 placed on the top side of the circuit board 302, in some embodiments, the contact pads 102 may additionally or alternatively be placed on the bottom side of the circuit board 302.

In the illustrative embodiment, the circuit board 302 is made from fiberglass and resin, such as FR-4. In other embodiments, other types of circuit board 302 may be used. In some embodiments, the contact pads 102 may be transferred to an integrated circuit component instead of an FR-4 circuit board, such as a die, chip, system-on-a-chip, etc. The illustrative circuit board 302 may have any suitable length or width, such as 10-500 millimeters. The circuit board 302 may have any suitable thickness, such as 0.2-5 millimeters.

The circuit board 302 includes an array of landing pads 304. In the illustrative embodiment, each landing pad 304 is made of copper. In other embodiments, other materials such as aluminum may be used and/or the landing pad 304 may be coated with another material, such as tin or nickel. In the illustrative embodiment, there is a landing pad 304 for each contact pad 102. In some embodiments, a landing pad 304 may not have a corresponding contact pad 102 and/or a contact pad 102 may not have a corresponding landing pad 304. Each landing pad 304 may have the same length and width as the contact pad 102, or the landing pad 304 may be larger or smaller than the corresponding contact pad 102.

In the illustrative embodiment, each landing pad 304 is connected to or forms part of a via 402 that connects the landing pad 304 (and, when mated, the corresponding contact pad 102) to one or more other components or traces. Additionally or alternatively, in some embodiments, some or all of the landing pads 304 may be connected to a trace on an outer surface of the circuit board 302.

Before the pad carrier 100 is brought into contact with the circuit board 302, solder paste 404 is placed on each landing pad 304. In the illustrative embodiment, the solder paste 404 is a mixture of solder particles and flux and will, when heated, turn to solder. As used herein, solder means any combination of elements that result in a conductive alloy with a low melting point that may be used to join circuit components together. Solder may include lead or may be lead-free. For example, solder may refer to an alloy of lead and tin, an alloy of silver, copper, and tin, an alloy of silver, copper, tin, and zinc, etc. Solder may include tin, lead, copper, silver, bismuth, indium, zinc, antimony, etc. Solder may have any suitable melting temperature, such as 150-250° C.

The pad carrier 100 can be brought into contact with the circuit board 302, with the tin plate layer 208 in contact with the solder paste 404. The circuit board 302 and pad carrier 100 are heated, such as in a reflow oven, and the solder paste 404 liquefies and then, upon cooling, forms a solder joint 502, joining each landing pad 304 and the contact pad 102, as shown in FIG. 5.

After the contact pads 102 are joined to the circuit board 302, the substrate 104 and frame 106 can be removed. In the illustrative embodiment, the flexible film of the substrate 104 can be peeled away from the contact pads 102. The adhesive layer 202 may be removed when the substrate 104 is peeled away, or the adhesive layer may be removed from the contact pad 102 through physical and/or chemical cleaning. Additionally or alternatively, in some embodiments, the substrate 104 may be chemically removed, such as being dissolved in a solvent that will not damage the circuit board 302 or contact pads 102.

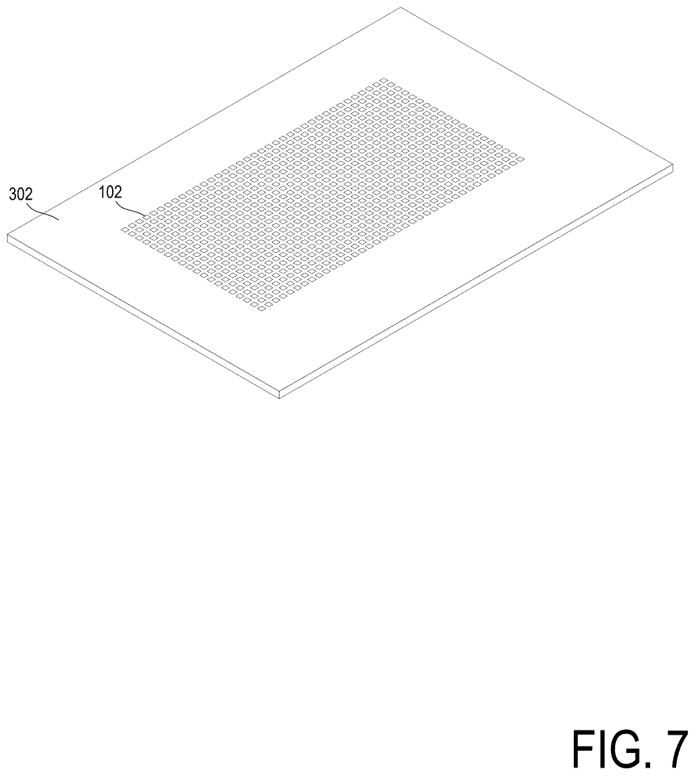

The resulting circuit board 302 has gold-plated contact pads 102 mated with it, as shown in FIG. 7. The contact pads 102 are all free to move relative to each other as the circuit board 302 expands or contracts, and so the contact pads 102 (and the solder joints 502) will not be under stress due to thermal expansion of the circuit board 302. The entire circuit board 302 did not need to go through a gold-plating process in order to plate the relatively small area of the contact pads 102, which may reduce costs. It should be appreciated that the circuit board 302 may include other components not shown, such as capacitors, resistors, other integrated circuit components, surface mounted components, ball grid array components, additional arrays of contact pads 102, etc. In some embodiments, an array of contact pads 102 may be built up in sections, such as by applying a pad carrier 100 to each section.

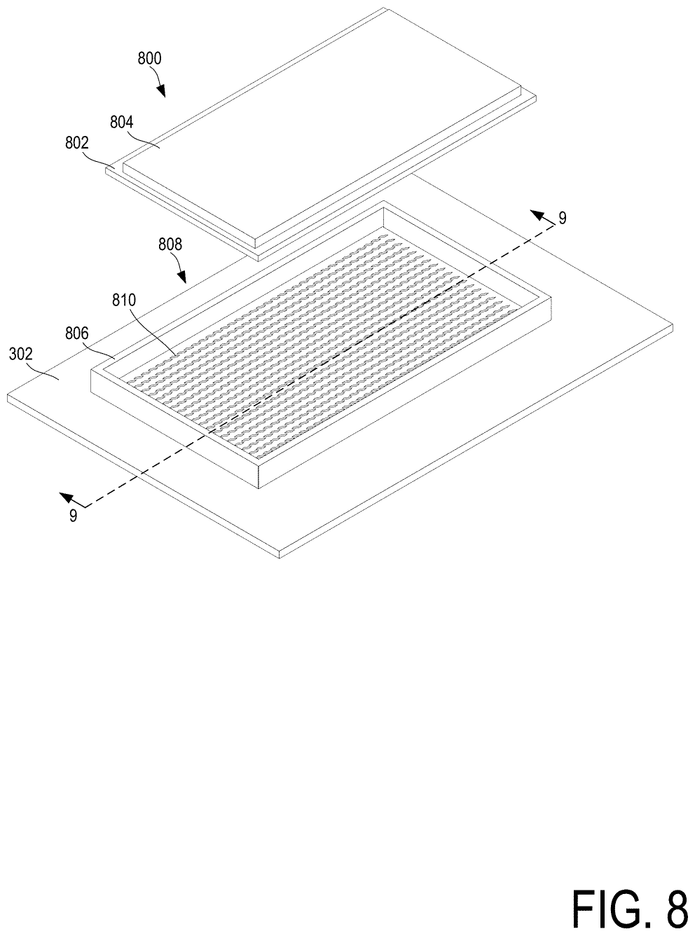

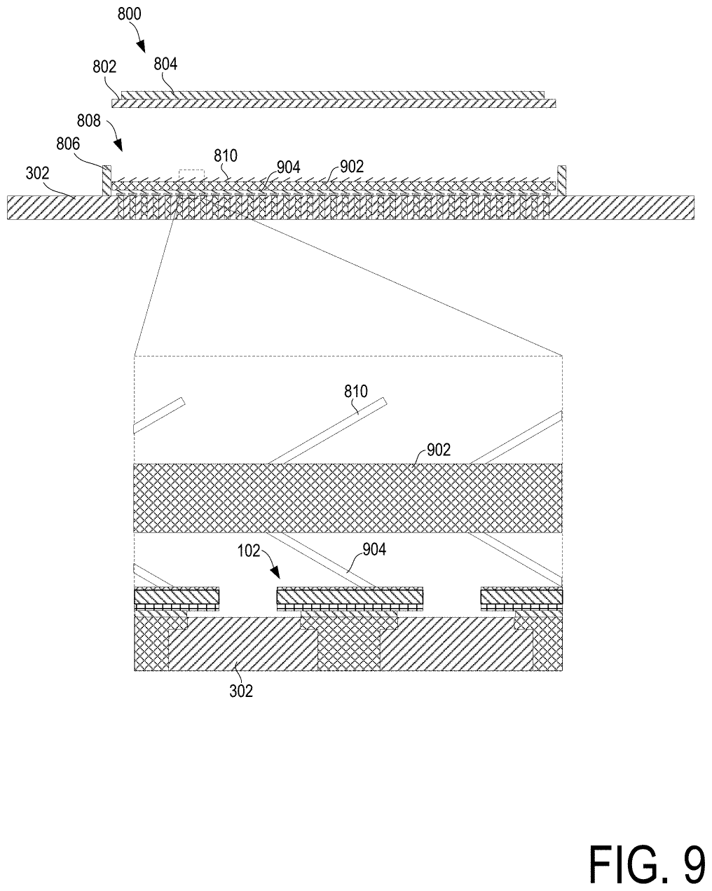

Referring now to FIG. 8, in one embodiment, a socket 806 for an integrated circuit component 800 may be mounted on the circuit board 302. A cross-sectional view of the circuit board 302 with the socket 806 is shown in FIG. 9. The socket 806 includes an array 808 of pins 810. Each pin 810 is configured to contact a corresponding pad on the integrated circuit component 800. The socket 806 also includes pins 904 on the opposite side (see FIG. 9). Each pin 904 is configured to contact a corresponding contact pad 102 of the circuit board 302.

The illustrative integrated circuit component includes a circuit board 802 and an integrated heat spreader 804. The integrated circuit component 800 may include one or more dies, chips, or other components connected to the circuit board 802. The integrated circuit component 800 may be or otherwise include, e.g., a processor, a memory, an accelerator device, etc. The integrated circuit component 800 may be secured in place with one or more fasteners, such as a clip, a spring screw, screws, bolts, land grid array (LGA) loading mechanism, etc. In some embodiments, a heat sink may be held in by one or more such fasteners, which may transfer a force to the integrated circuit component 800 towards the socket 806.

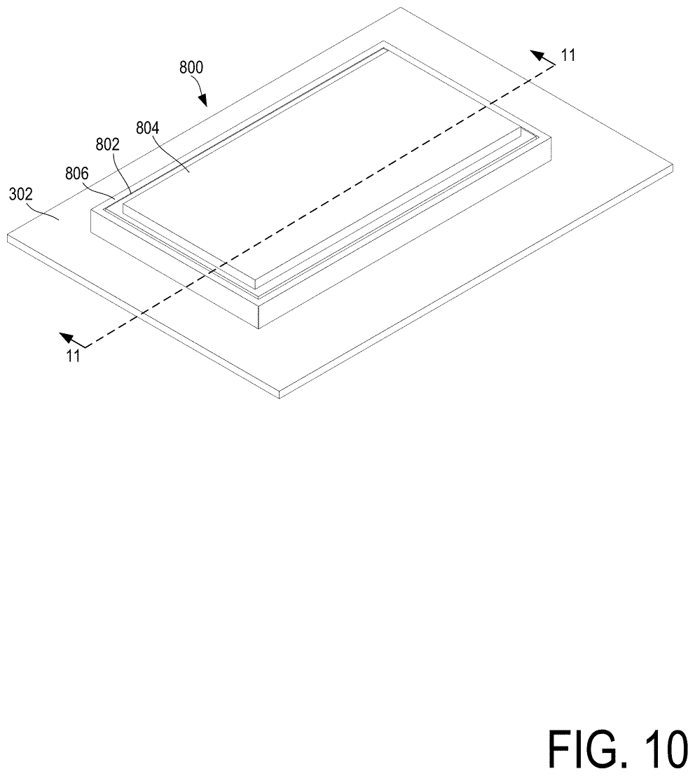

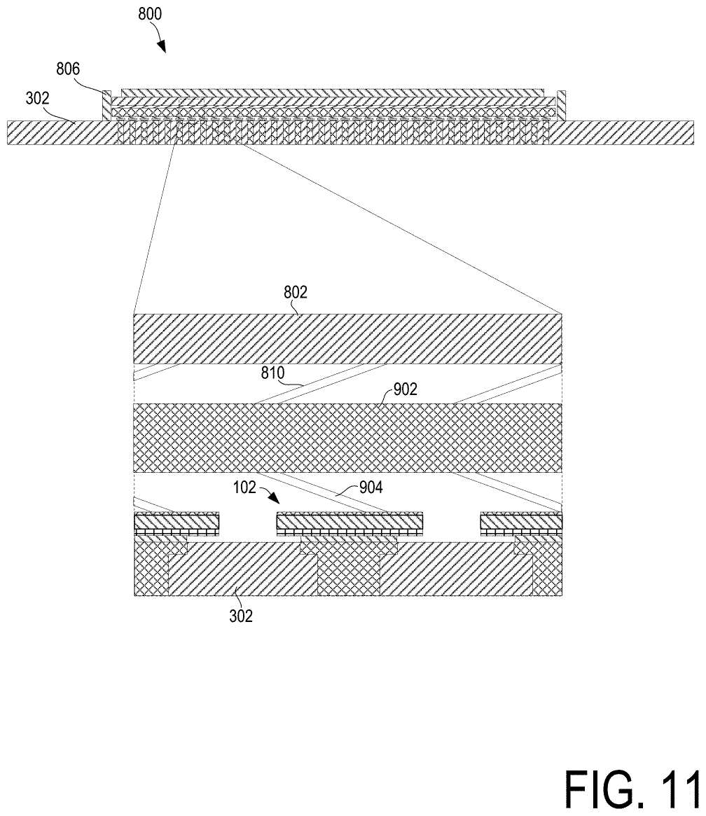

Referring now to FIGS. 10 and 11, the integrated circuit component 800 is mated with the socket 806. In the illustrative embodiment, the integrated circuit component 800 is pressed into the socket 806, such as by a heat sink or other retaining mechanism. The pressure on the integrated circuit component 800 flexes the pins 810, 904, ensuring good electrical contact between each pin 810, 904 and the corresponding contact pad.

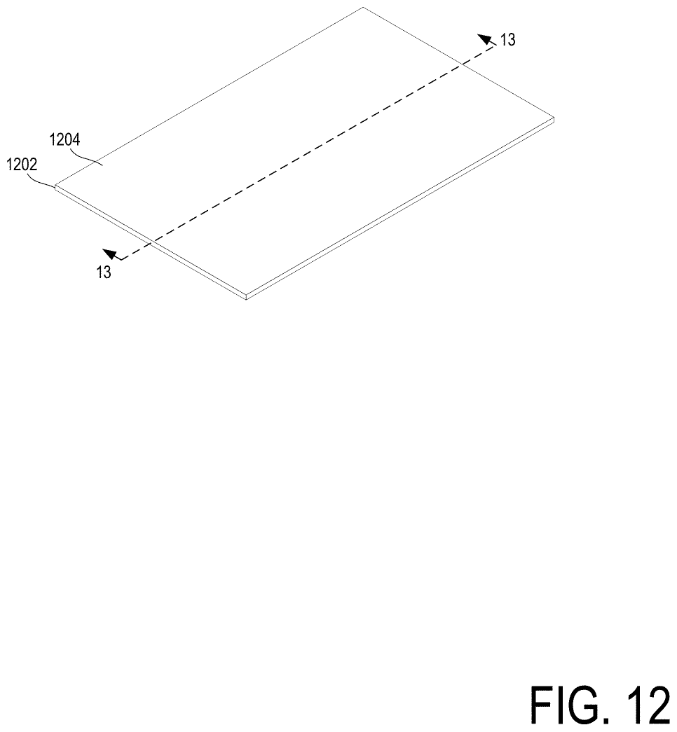

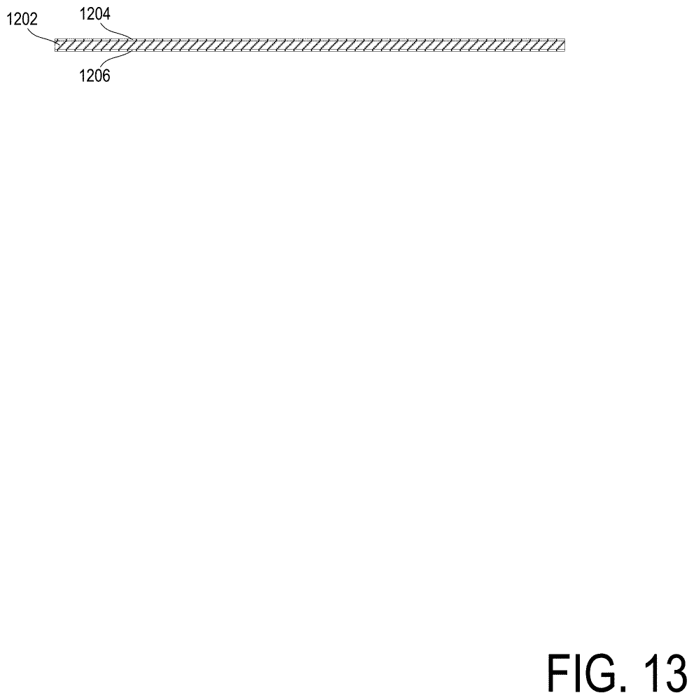

Referring now to FIG. 12, in one embodiment, a substrate 1202 has a first copper layer 1204 on one side of it and a second copper layer 1206 on the other side of it. A cross-sectional view of FIG. 12 is shown in FIG. 13. The substrate 1202 may be any suitable flexible or inflexible substrate, such as a weaving of glass fibers impregnated with a resin, also known as a prepreg. The dimensions of the substrate 1202 may be similar to those of the substrate 104 described above.

In the illustrative embodiment, each copper layer 1204, 1206 fully covers the substrate 1202. In other embodiments, each copper layer 1204, 1206 may cover less than the entire substrate 1202. Each copper layer 1204, 1206 may be any suitable thickness, such as 5-100 micrometers.

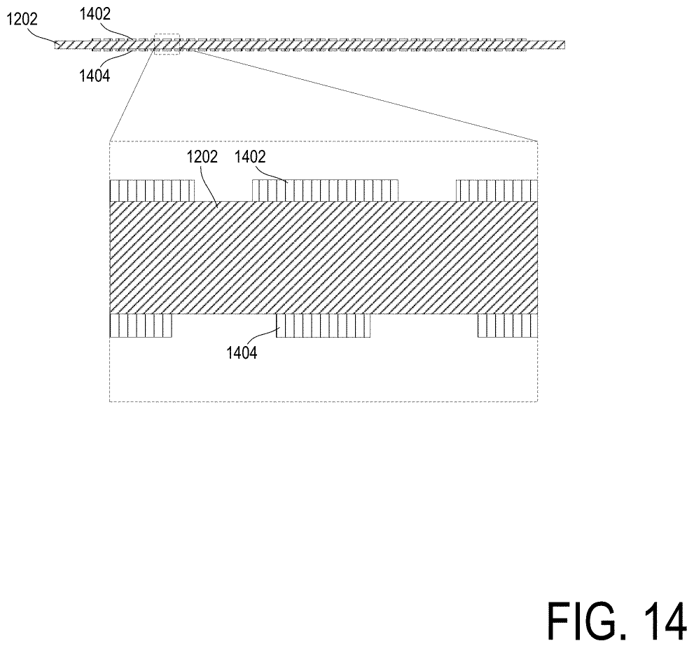

Referring now to FIG. 14, an array of contact pads 1402, 1404 may be formed from the copper layers 1204, 1206. The contact pads 1402, 1404 may be formed in any suitable manner, such as using photolithography and etching. Each contact pad 1402, 1404 may have similar dimensions as the copper layer 206 of the contact pad 102 described above, and the number and/or arrangement of contact pads 1402, 1404 may be similar to that for the contact pads 102 described above. In some embodiments, the lower contact pad 1404 may be smaller than the upper contact pad 1402. For example, the upper contact pad 1402 may have an area of 0.5 mm², and the lower contact pad 1404 may have an area of 0.25 mm². More generally, the area of the lower contact pad 1404 may be, e.g., 5-100% of the area of the upper contact pad 1402. Such a configuration would allow for a relatively large contact pad 1402 for mating with, e.g., a socket or an integrated circuit component, while allowing traces, ground planes, etc., to be between the lower contact pads 1404 on the outer surface of a circuit board the substrate 1202 is mated to.

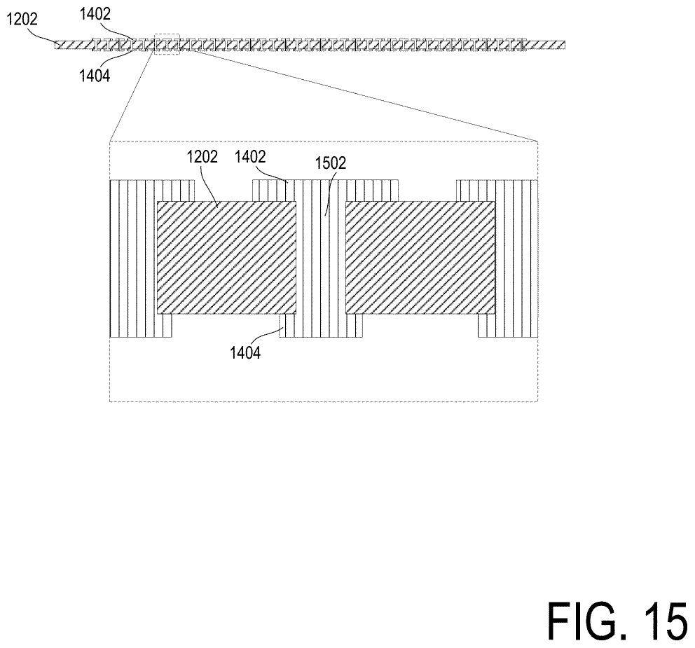

Referring now to FIG. 15, a via 1502 is formed between each upper contact pad 1402 and lower contact pad 1404, electrically connected each pair of upper contact pads 1402 and lower contact pads 1404. The via 1502 may be formed in any suitable manner, such as using a mechanical drill, a laser drill, photolithography techniques, etc. In the illustrative embodiment, the vias 1502 are filled with a conductive material such as copper or conductive epoxy. In the illustrative embodiment, the vias 1502 are microvias. In some embodiments, the copper may be plated with nickel.

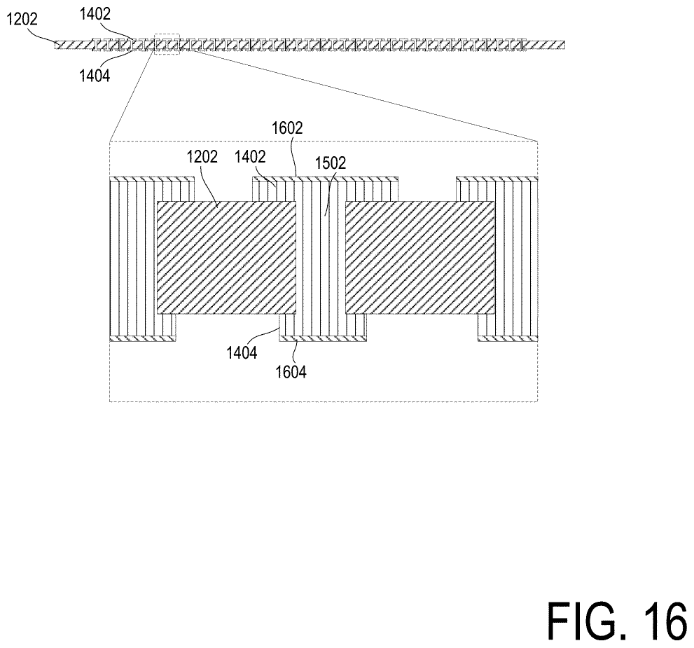

Referring now to FIG. 16, the upper contact pad 1402 has a gold plate layer 1602 plated onto it. The gold plate layer 1602 may be plated using, e.g., electroless nickel immersion gold plating, electrolytic gold plating, etc. In the illustrative embodiment, the lower contact pad 1402 has a layer 1604 plated on it as well. The layer 1604 may be tin, gold, or other suitable material. In some embodiments, a layer of OSP may be applied.

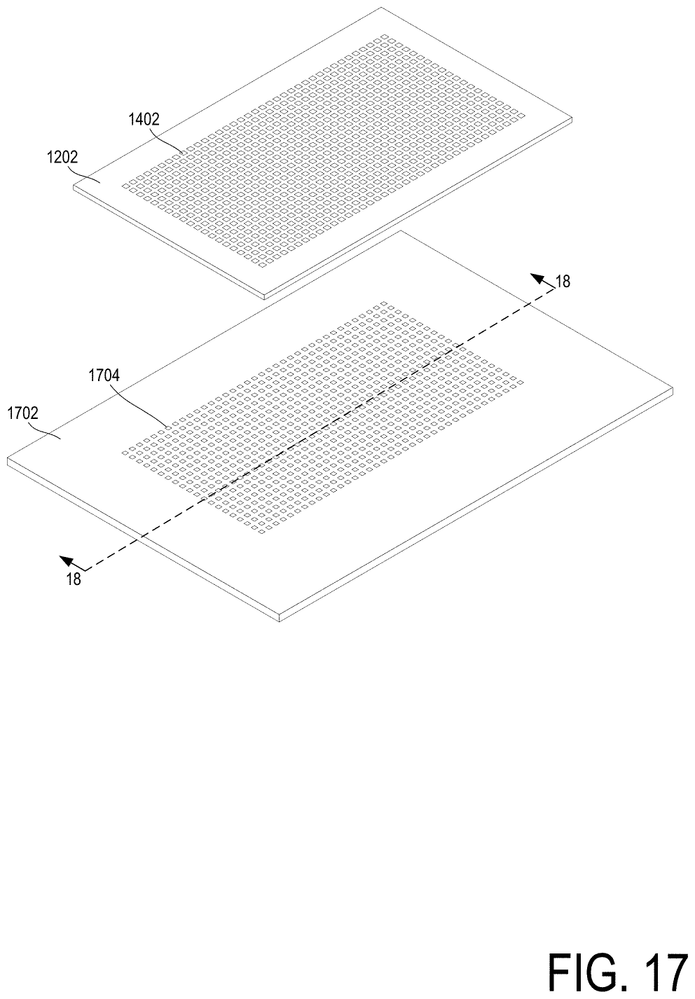

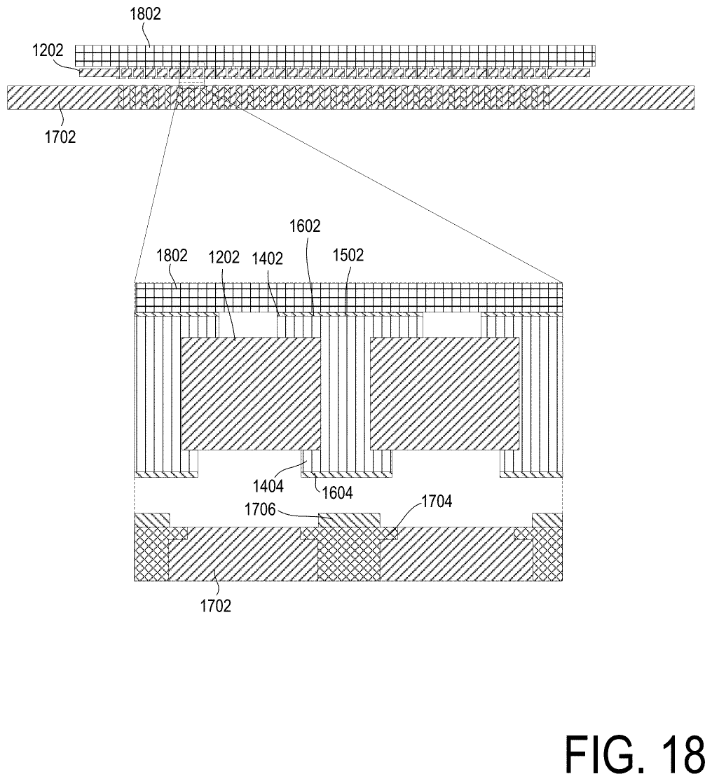

Referring now to FIGS. 17 and 18, the substrate 1202 is shown above a circuit board 1702. FIG. 18 shows a cross-sectional side view of the circuit board 1702 and substrate 1202. The circuit board 1702 has an array of landing pads 1704 with solder paste 1706 on them. The circuit board 1702, landing pads 1704, and solder paste 1706 may be similar to the circuit board 302, landing pads 304, and solder paste 404 described above, which will not be repeated in the interest of clarity. In some embodiments, a stiffener 1802 may be used to apply even force to the substrate 1202 as it is mated with the circuit board 1702. The stiffener 1802 may be any suitable material, such as metal, wood, plastic, etc. In some embodiments, multiple substrates 1202 may be attached to the same stiffener 1802 to be applied at the same time, which may increase yield.

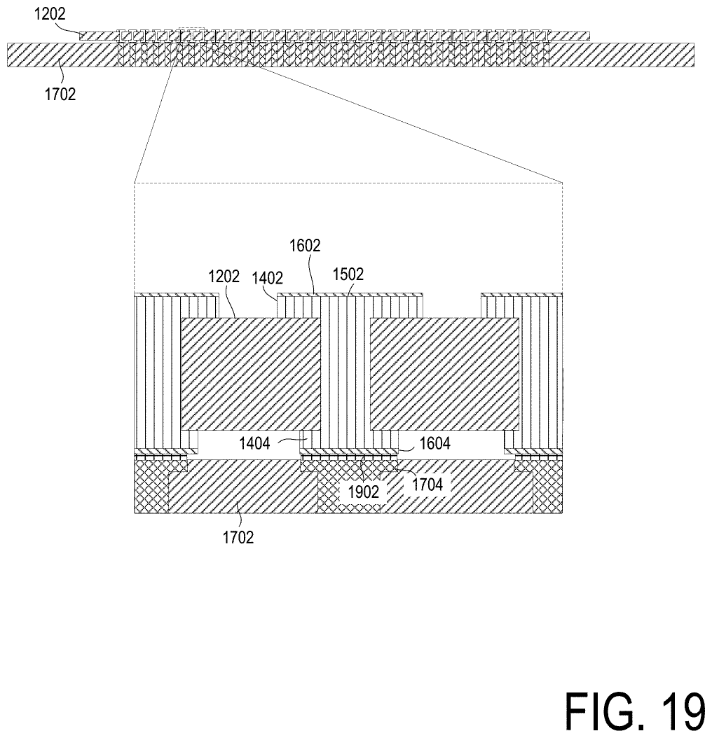

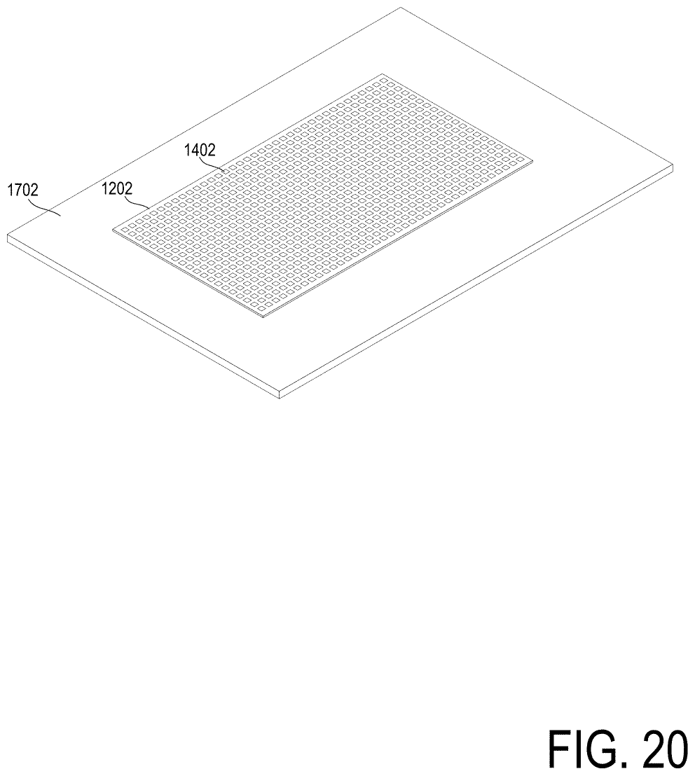

Referring now to FIG. 19, the substrate 1202 can be brought into contact with the circuit board 1702, with the lower contact pad 1404 in contact with the solder paste 1706. The circuit board 1702 and substrate 1202 are heated, such as in a reflow oven, and the solder paste 1706 liquefies and then, upon cooling, forms a joint of solder 1902, electrically connecting each landing pad 1704 to the corresponding top gold-plated contact pad 1402 by the corresponding via 1502. FIG. 20 shows an isometric view of the circuit board 1702 with the substrate 1202 and contact pads 1402 mated to it.

A socket 806 and/or integrated circuit component 800 may be mounted on the circuit board 1702 in a similar manner as for the circuit board 302 described above in regard to FIGS. 8-11, a description of which will not be repeated in the interest of clarity.

It should be appreciated that the techniques described herein for applying gold-plated contact pads 102, 1402 may be used for other purposes besides mounting a socket 806 and/or an integrated circuit component 800 on the circuit board 302, 1702. The application of the gold-plated contact pads 102, 1402 may all for any suitable component to be pressure mounted to the circuit board 302, 1702, such as a connector, an expansion component, etc. More generally, the techniques described herein allow for selective gold plating of a circuit board 302.

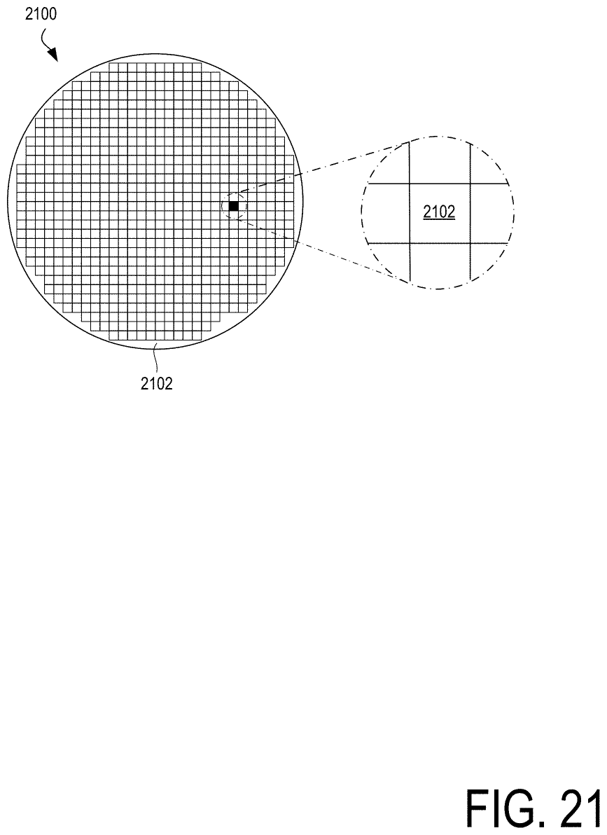

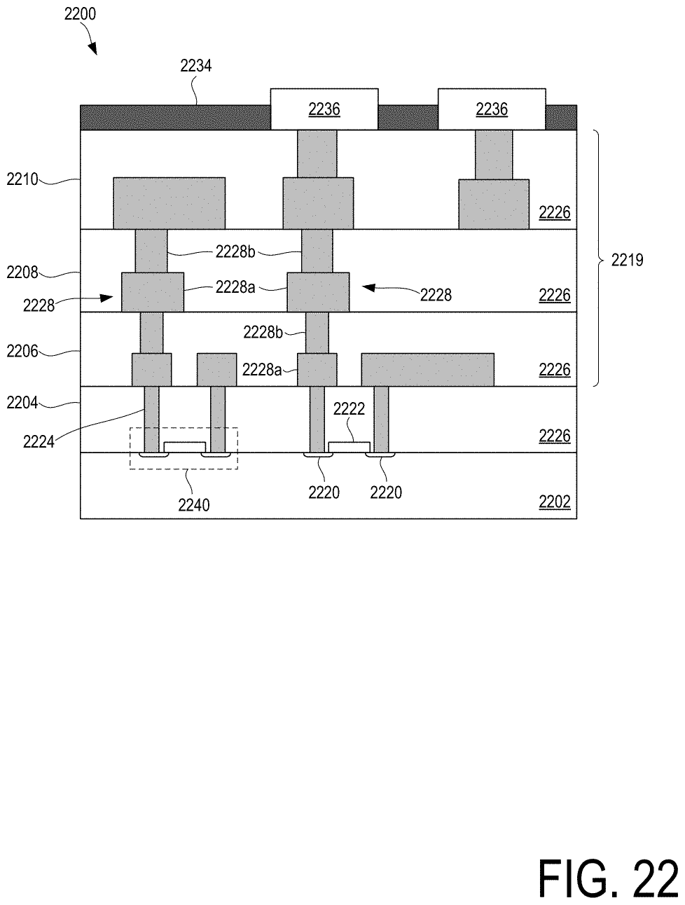

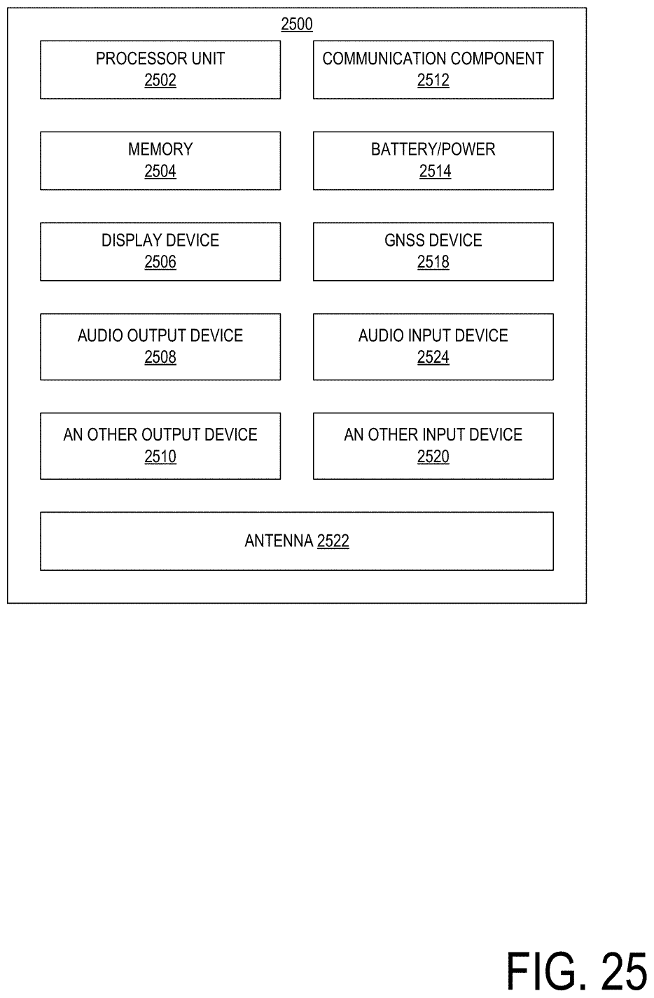

FIG. 21 is a top view of a wafer 2100 and dies 2102 that may be included on any of the circuit boards 302, 1702 disclosed herein (e.g., in any suitable integrated circuit component 800). The wafer 2100 may be composed of semiconductor material and may include one or more dies 2102 having integrated circuit structures formed on a surface of the wafer 2100. The individual dies 2102 may be a repeating unit of an integrated circuit product that includes any suitable integrated circuit. After the fabrication of the semiconductor product is complete, the wafer 2100 may undergo a singulation process in which the dies 2102 are separated from one another to provide discrete “chips” of the integrated circuit product. The die 2102 may include one or more transistors (e.g., some of the transistors 2240 of FIG. 22, discussed below), supporting circuitry to route electrical signals to the transistors, passive components (e.g., signal traces, resistors, capacitors, or inductors), and/or any other integrated circuit components. In some embodiments, the wafer 2100 or the die 2102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 2102. For example, a memory array formed by multiple memory devices may be formed on a same die 2102 as a processor unit (e.g., the processor unit 2502 of FIG. 25) or other logic that is configured to store information in the memory devices or execute instructions stored in the memory array.

FIG. 22 is a cross-sectional side view of an integrated circuit device 2200 that may be included on any of the circuit boards 302, 1702 disclosed herein (e.g., in any suitable integrated circuit component 800). One or more of the integrated circuit devices 2200 may be included in one or more dies 2102 (FIG. 21). The integrated circuit device 2200 may be formed on a die substrate 2202 (e.g., the wafer 2100 of FIG. 21) and may be included in a die (e.g., the die 2102 of FIG. 21). The die substrate 2202 may be a semiconductor substrate composed of semiconductor material systems including, for example, n-type or p-type materials systems (or a combination of both). The die substrate 2202 may include, for example, a crystalline substrate formed using a bulk silicon or a silicon-on-insulator (SOI) substructure. In some embodiments, the die substrate 2202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 2202. Although a few examples of materials from which the die substrate 2202 may be formed are described here, any material that may serve as a foundation for an integrated circuit device 2200 may be used. The die substrate 2202 may be part of a singulated die (e.g., the dies 2102 of FIG. 21) or a wafer (e.g., the wafer 2100 of FIG. 21).

The integrated circuit device 2200 may include one or more device layers 2204 disposed on the die substrate 2202. The device layer 2204 may include features of one or more transistors 2240 (e.g., metal oxide semiconductor field-effect transistors (MOSFETs)) formed on the die substrate 2202. The transistors 2240 may include, for example, one or more source and/or drain (S/D) regions 2220, a gate 2222 to control current flow between the S/D regions 2220, and one or more S/D contacts 2224 to route electrical signals to/from the S/D regions 2220. The transistors 2240 may include additional features not depicted for the sake of clarity, such as device isolation regions, gate contacts, and the like. The transistors 2240 are not limited to the type and configuration depicted in FIG. 22 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

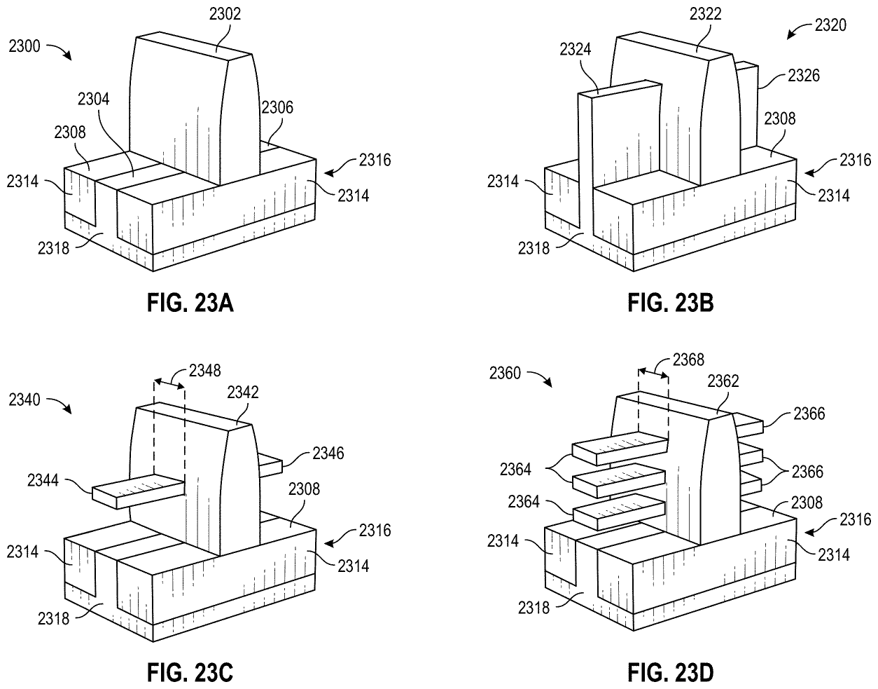

FIGS. 23A-23D are simplified perspective views of example planar, FinFET, gate-all-around, and stacked gate-all-around transistors. The transistors illustrated in FIGS. 23A-23D are formed on a substrate 2316 having a surface 2308. Isolation regions 2314 separate the source and drain regions of the transistors from other transistors and from a bulk region 2318 of the substrate 2316.

FIG. 23A is a perspective view of an example planar transistor 2300 comprising a gate 2302 that controls current flow between a source region 2304 and a drain region 2306. The transistor 2300 is planar in that the source region 2304 and the drain region 2306 are planar with respect to the substrate surface 2308.

FIG. 23B is a perspective view of an example FinFET transistor 2320 comprising a gate 2322 that controls current flow between a source region 2324 and a drain region 2326. The transistor 2320 is non-planar in that the source region 2324 and the drain region 2326 comprise “fins” that extend upwards from the substrate surface 2328. As the gate 2322 encompasses three sides of the semiconductor fin that extends from the source region 2324 to the drain region 2326, the transistor 2320 can be considered a tri-gate transistor. FIG. 23B illustrates one S/D fin extending through the gate 2322, but multiple S/D fins can extend through the gate of a FinFET transistor.

FIG. 23C is a perspective view of a gate-all-around (GAA) transistor 2340 comprising a gate 2342 that controls current flow between a source region 2344 and a drain region 2346. The transistor 2340 is non-planar in that the source region 2344 and the drain region 2346 are elevated from the substrate surface 2328.

FIG. 23D is a perspective view of a GAA transistor 2360 comprising a gate 2362 that controls current flow between multiple elevated source regions 2364 and multiple elevated drain regions 2366. The transistor 2360 is a stacked GAA transistor as the gate controls the flow of current between multiple elevated S/D regions stacked on top of each other. The transistors 2340 and 2360 are considered gate-all-around transistors as the gates encompass all sides of the semiconductor portions that extends from the source regions to the drain regions. The transistors 2340 and 2360 can alternatively be referred to as nanowire, nanosheet, or nanoribbon transistors depending on the width (e.g., widths 2348 and 2368 of transistors 2340 and 2360, respectively) of the semiconductor portions extending through the gate.

Returning to FIG. 22, a transistor 2240 may include a gate 2222 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 2240 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 2240 along the source-channel-drain direction, the gate electrode may consist of a U-shaped structure that includes a bottom portion substantially parallel to the surface of the die substrate 2202 and two sidewall portions that are substantially perpendicular to the top surface of the die substrate 2202. In other embodiments, at least one of the metal layers that form the gate electrode may simply be a planar layer that is substantially parallel to the top surface of the die substrate 2202 and does not include sidewall portions substantially perpendicular to the top surface of the die substrate 2202. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 2220 may be formed within the die substrate 2202 adjacent to the gate 2222 of individual transistors 2240. The S/D regions 2220 may be formed using an implantation/diffusion process or an etching/deposition process, for example. In the former process, dopants such as boron, aluminum, antimony, phosphorous, or arsenic may be ion-implanted into the die substrate 2202 to form the S/D regions 2220. An annealing process that activates the dopants and causes them to diffuse farther into the die substrate 2202 may follow the ion-implantation process. In the latter process, the die substrate 2202 may first be etched to form recesses at the locations of the S/D regions 2220. An epitaxial deposition process may then be carried out to fill the recesses with material that is used to fabricate the S/D regions 2220. In some implementations, the S/D regions 2220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 2220 may be formed using one or more alternate semiconductor materials such as germanium or a group III-V material or alloy. In further embodiments, one or more layers of metal and/or metal alloys may be used to form the S/D regions 2220.

Electrical signals, such as power and/or input/output (I/O) signals, may be routed to and/or from the devices (e.g., transistors 2240) of the device layer 2204 through one or more interconnect layers disposed on the device layer 2204 (illustrated in FIG. 22 as interconnect layers 2206-2210). For example, electrically conductive features of the device layer 2204 (e.g., the gate 2222 and the S/D contacts 2224) may be electrically coupled with the interconnect structures 2228 of the interconnect layers 2206-2210. The one or more interconnect layers 2206-2210 may form a metallization stack (also referred to as an “ILD stack”) 2219 of the integrated circuit device 2200.

The interconnect structures 2228 may be arranged within the interconnect layers 2206-2210 to route electrical signals according to a wide variety of designs; in particular, the arrangement is not limited to the particular configuration of interconnect structures 2228 depicted in FIG. 22. Although a particular number of interconnect layers 2206-2210 is depicted in FIG. 22, embodiments of the present disclosure include integrated circuit devices having more or fewer interconnect layers than depicted.

In some embodiments, the interconnect structures 2228 may include lines 2228a and/or vias 2228b filled with an electrically conductive material such as a metal. The lines 2228a may be arranged to route electrical signals in a direction of a plane that is substantially parallel with a surface of the die substrate 2202 upon which the device layer 2204 is formed. The vias 2228b may be arranged to route electrical signals in a direction of a plane that is substantially perpendicular to the surface of the die substrate 2202 upon which the device layer 2204 is formed. In some embodiments, the vias 2228b may electrically couple lines 2228a of different interconnect layers 2206-2210 together.

The interconnect layers 2206-2210 may include a dielectric material 2226 disposed between the interconnect structures 2228, as shown in FIG. 22. In some embodiments, dielectric material 2226 disposed between the interconnect structures 2228 in different ones of the interconnect layers 2206-2210 may have different compositions; in other embodiments, the composition of the dielectric material 2226 between different interconnect layers 2206-2210 may be the same. The device layer 2204 may include a dielectric material 2226 disposed between the transistors 2240 and a bottom layer of the metallization stack as well. The dielectric material 2226 included in the device layer 2204 may have a different composition than the dielectric material 2226 included in the interconnect layers 2206-2210; in other embodiments, the composition of the dielectric material 2226 in the device layer 2204 may be the same as a dielectric material 2226 included in any one of the interconnect layers 2206-2210.

A first interconnect layer 2206 (referred to as Metal 1 or “M1”) may be formed directly on the device layer 2204. In some embodiments, the first interconnect layer 2206 may include lines 2228a and/or vias 2228b, as shown. The lines 2228a of the first interconnect layer 2206 may be coupled with contacts (e.g., the S/D contacts 2224) of the device layer 2204. The vias 2228b of the first interconnect layer 2206 may be coupled with the lines 2228a of a second interconnect layer 2208.

The second interconnect layer 2208 (referred to as Metal 2 or “M2”) may be formed directly on the first interconnect layer 2206. In some embodiments, the second interconnect layer 2208 may include via 2228b to couple the lines 2228 of the second interconnect layer 2208 with the lines 2228a of a third interconnect layer 2210. Although the lines 2228a and the vias 2228b are structurally delineated with a line within individual interconnect layers for the sake of clarity, the lines 2228a and the vias 2228b may be structurally and/or materially contiguous (e.g., simultaneously filled during a dual-damascene process) in some embodiments.

The third interconnect layer 2210 (referred to as Metal 3 or “M3”) (and additional interconnect layers, as desired) may be formed in succession on the second interconnect layer 2208 according to similar techniques and configurations described in connection with the second interconnect layer 2208 or the first interconnect layer 2206. In some embodiments, the interconnect layers that are “higher up” in the metallization stack 2219 in the integrated circuit device 2200 (i.e., farther away from the device layer 2204) may be thicker that the interconnect layers that are lower in the metallization stack 2219, with lines 2228a and vias 2228b in the higher interconnect layers being thicker than those in the lower interconnect layers.

The integrated circuit device 2200 may include a solder resist material 2234 (e.g., polyimide or similar material) and one or more conductive contacts 2236 formed on the interconnect layers 2206-2210. In FIG. 22, the conductive contacts 2236 are illustrated as taking the form of bond pads. The conductive contacts 2236 may be electrically coupled with the interconnect structures 2228 and configured to route the electrical signals of the transistor(s) 2240 to external devices. For example, solder bonds may be formed on the one or more conductive contacts 2236 to mechanically and/or electrically couple an integrated circuit die including the integrated circuit device 2200 with another component (e.g., a printed circuit board). The integrated circuit device 2200 may include additional or alternate structures to route the electrical signals from the interconnect layers 2206-2210; for example, the conductive contacts 2236 may include other analogous features (e.g., posts) that route the electrical signals to external components.

In some embodiments in which the integrated circuit device 2200 is a double-sided die, the integrated circuit device 2200 may include another metallization stack (not shown) on the opposite side of the device layer(s) 2204. This metallization stack may include multiple interconnect layers as discussed above with reference to the interconnect layers 2206-2210, to provide conductive pathways (e.g., including conductive lines and vias) between the device layer(s) 2204 and additional conductive contacts (not shown) on the opposite side of the integrated circuit device 2200 from the conductive contacts 2236.

In other embodiments in which the integrated circuit device 2200 is a double-sided die, the integrated circuit device 2200 may include one or more through silicon vias (TSVs) through the die substrate 2202; these TSVs may make contact with the device layer(s) 2204, and may provide conductive pathways between the device layer(s) 2204 and additional conductive contacts (not shown) on the opposite side of the integrated circuit device 2200 from the conductive contacts 2236. In some embodiments, TSVs extending through the substrate can be used for routing power and ground signals from conductive contacts on the opposite side of the integrated circuit device 2200 from the conductive contacts 2236 to the transistors 2240 and any other components integrated into the die 2200, and the metallization stack 2219 can be used to route I/O signals from the conductive contacts 2236 to transistors 2240 and any other components integrated into the die 2200.

Multiple integrated circuit devices 2200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

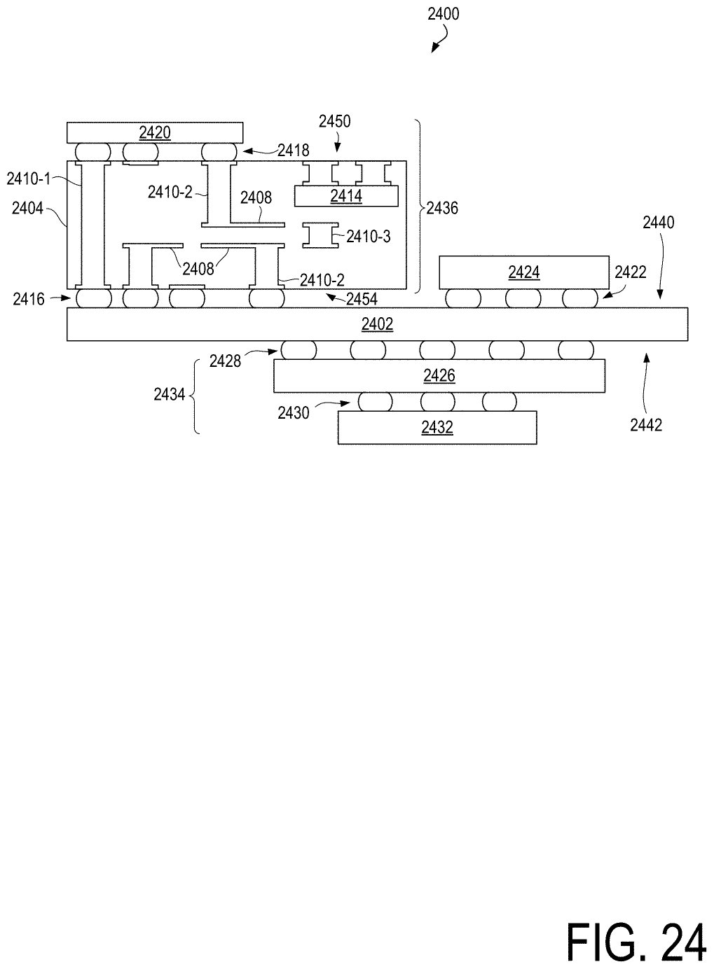

FIG. 24 is a cross-sectional side view of an integrated circuit device assembly 2400. The integrated circuit device assembly 2400 includes a number of components disposed on a circuit board 2402 (which may be a motherboard, system board, mainboard, etc.). The integrated circuit device assembly 2400 includes components disposed on a first face 2440 of the circuit board 2402 and an opposing second face 2442 of the circuit board 2402; generally, components may be disposed on one or both faces 2440 and 2442.

In some embodiments, the circuit board 2402 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 2402. In other embodiments, the circuit board 2402 may be a non-PCB substrate. In some embodiments the circuit board 2402 may be, for example, the circuit board 302 or 1702. The integrated circuit device assembly 2400 illustrated in FIG. 24 includes a package-on-interposer structure 2436 coupled to the first face 2440 of the circuit board 2402 by coupling components 2416. The coupling components 2416 may electrically and mechanically couple the package-on-interposer structure 2436 to the circuit board 2402, and may include solder balls (as shown in FIG. 24), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 2436 may include an integrated circuit component 2420 coupled to an interposer 2404 by coupling components 2418. The coupling components 2418 may take any suitable form for the application, such as the forms discussed above with reference to the coupling components 2416. Although a single integrated circuit component 2420 is shown in FIG. 24, multiple integrated circuit components may be coupled to the interposer 2404; indeed, additional interposers may be coupled to the interposer 2404. The interposer 2404 may provide an intervening substrate used to bridge the circuit board 2402 and the integrated circuit component 2420.

The integrated circuit component 2420 may be a packaged or unpacked integrated circuit product that includes one or more integrated circuit dies (e.g., the die 2102 of FIG. 21, the integrated circuit device 2200 of FIG. 22) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 2420, a single monolithic integrated circuit die comprises solder bumps attached to contacts on the die. The solder bumps allow the die to be directly attached to the interposer 2404. The integrated circuit component 2420 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 2420 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 2420 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 2420 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 2404 may spread connections to a wider pitch or reroute a connection to a different connection. For example, the interposer 2404 may couple the integrated circuit component 2420 to a set of ball grid array (BGA) conductive contacts of the coupling components 2416 for coupling to the circuit board 2402. In the embodiment illustrated in FIG. 24, the integrated circuit component 2420 and the circuit board 2402 are attached to opposing sides of the interposer 2404; in other embodiments, the integrated circuit component 2420 and the circuit board 2402 may be attached to a same side of the interposer 2404. In some embodiments, three or more components may be interconnected by way of the interposer 2404.

In some embodiments, the interposer 2404 may be formed as a PCB, including multiple metal layers separated from one another by layers of dielectric material and interconnected by electrically conductive vias. In some embodiments, the interposer 2404 may be formed of an epoxy resin, a fiberglass-reinforced epoxy resin, an epoxy resin with inorganic fillers, a ceramic material, or a polymer material such as polyimide. In some embodiments, the interposer 2404 may be formed of alternate rigid or flexible materials that may include the same materials described above for use in a semiconductor substrate, such as silicon, germanium, and other group III-V and group IV materials. The interposer 2404 may include metal interconnects 2408 and vias 2410, including but not limited to through hole vias 2410-1 (that extend from a first face 2450 of the interposer 2404 to a second face 2454 of the interposer 2404), blind vias 2410-2 (that extend from the first or second faces 2450 or 2454 of the interposer 2404 to an internal metal layer), and buried vias 2410-3 (that connect internal metal layers).

In some embodiments, the interposer 2404 can comprise a silicon interposer. Through silicon vias (TSV) extending through the silicon interposer can connect connections on a first face of a silicon interposer to an opposing second face of the silicon interposer. In some embodiments, an interposer 2404 comprising a silicon interposer can further comprise one or more routing layers to route connections on a first face of the interposer 2404 to an opposing second face of the interposer 2404.

The interposer 2404 may further include embedded devices 2414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2404. The package-on-interposer structure 2436 may take the form of any of the package-on-interposer structures known in the art. In embodiments where the interposer is a non-printed circuit board

The integrated circuit device assembly 2400 may include an integrated circuit component 2424 coupled to the first face 2440 of the circuit board 2402 by coupling components 2422. The coupling components 2422 may take the form of any of the embodiments discussed above with reference to the coupling components 2416, and the integrated circuit component 2424 may take the form of any of the embodiments discussed above with reference to the integrated circuit component 2420.

The integrated circuit device assembly 2400 illustrated in FIG. 24 includes a package-on-package structure 2434 coupled to the second face 2442 of the circuit board 2402 by coupling components 2428. The package-on-package structure 2434 may include an integrated circuit component 2426 and an integrated circuit component 2432 coupled together by coupling components 2430 such that the integrated circuit component 2426 is disposed between the circuit board 2402 and the integrated circuit component 2432. The coupling components 2428 and 2430 may take the form of any of the embodiments of the coupling components 2416 discussed above, and the integrated circuit components 2426 and 2432 may take the form of any of the embodiments of the integrated circuit component 2420 discussed above. The package-on-package structure 2434 may be configured in accordance with any of the package-on-package structures known in the art.

FIG. 25 is a block diagram of an example electrical device 2500 that may include one or more of the circuit boards 302, 1702 disclosed herein. For example, any suitable ones of the components of the electrical device 2500 may include one or more of the integrated circuit device assemblies 2400, integrated circuit components 2420, integrated circuit devices 2200, or integrated circuit dies 2102 disclosed herein. A number of components are illustrated in FIG. 25 as included in the electrical device 2500, but any one or more of these components may be omitted or duplicated, as suitable for the application. In some embodiments, some or all of the components included in the electrical device 2500 may be attached to one or more motherboards mainboards, or system boards. In some embodiments, one or more of these components are fabricated onto a single system-on-a-chip (SoC) die.

Additionally, in various embodiments, the electrical device 2500 may not include one or more of the components illustrated in FIG. 25, but the electrical device 2500 may include interface circuitry for coupling to the one or more components. For example, the electrical device 2500 may not include a display device 2506, but may include display device interface circuitry (e.g., a connector and driver circuitry) to which a display device 2506 may be coupled. In another set of examples, the electrical device 2500 may not include an audio input device 2524 or an audio output device 2508, but may include audio input or output device interface circuitry (e.g., connectors and supporting circuitry) to which an audio input device 2524 or audio output device 2508 may be coupled.

The electrical device 2500 may include one or more processor units 2502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 2502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2500 may include a memory 2504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2504 may include memory that is located on the same integrated circuit die as the processor unit 2502. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 2500 can comprise one or more processor units 2502 that are heterogeneous or asymmetric to another processor unit 2502 in the electrical device 2500. There can be a variety of differences between the processing units 2502 in a system in terms of a spectrum of metrics of merit including architectural, microarchitectural, thermal, power consumption characteristics, and the like. These differences can effectively manifest themselves as asymmetry and heterogeneity among the processor units 2502 in the electrical device 2500.

In some embodiments, the electrical device 2500 may include a communication component 2512 (e.g., one or more communication components). For example, the communication component 2512 can manage wireless communications for the transfer of data to and from the electrical device 2500. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2512 may operate in accordance with other wireless protocols in other embodiments. The electrical device 2500 may include an antenna 2522 to facilitate wireless communications and/or to receive other wireless communications (such as AM or FM radio transmissions).

In some embodiments, the communication component 2512 may manage wired communications, such as electrical, optical, or any other suitable communication protocols (e.g., IEEE 802.3 Ethernet standards). As noted above, the communication component 2512 may include multiple communication components. For instance, a first communication component 2512 may be dedicated to shorter-range wireless communications such as Wi-Fi or Bluetooth, and a second communication component 2512 may be dedicated to longer-range wireless communications such as global positioning system (GPS), EDGE, GPRS, CDMA, WiMAX, LTE, EV-DO, or others. In some embodiments, a first communication component 2512 may be dedicated to wireless communications, and a second communication component 2512 may be dedicated to wired communications.

The electrical device 2500 may include battery/power circuitry 2514. The battery/power circuitry 2514 may include one or more energy storage devices (e.g., batteries or capacitors) and/or circuitry for coupling components of the electrical device 2500 to an energy source separate from the electrical device 2500 (e.g., AC line power).

The electrical device 2500 may include a display device 2506 (or corresponding interface circuitry, as discussed above). The display device 2506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2500 may include an audio output device 2508 (or corresponding interface circuitry, as discussed above). The audio output device 2508 may include any embedded or wired or wirelessly connected external device that generates an audible indicator, such speakers, headsets, or earbuds.

The electrical device 2500 may include an audio input device 2524 (or corresponding interface circuitry, as discussed above). The audio input device 2524 may include any embedded or wired or wirelessly connected device that generates a signal representative of a sound, such as microphones, microphone arrays, or digital instruments (e.g., instruments having a musical instrument digital interface (MIDI) output). The electrical device 2500 may include a Global Navigation Satellite System (GNSS) device 2518 (or corresponding interface circuitry, as discussed above), such as a Global Positioning System (GPS) device. The GNSS device 2518 may be in communication with a satellite-based system and may determine a geolocation of the electrical device 2500 based on information received from one or more GNSS satellites, as known in the art.

The electrical device 2500 may include an other output device 2510 (or corresponding interface circuitry, as discussed above). Examples of the other output device 2510 may include an audio codec, a video codec, a printer, a wired or wireless transmitter for providing information to other devices, or an additional storage device.

The electrical device 2500 may include an other input device 2520 (or corresponding interface circuitry, as discussed above). Examples of the other input device 2520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2500 may be any other electronic device that processes data. In some embodiments, the electrical device 2500 may comprise multiple discrete physical components. Given the range of devices that the electrical device 2500 can be manifested as in various embodiments, in some embodiments, the electrical device 2500 can be referred to as a computing device or a computing system.

### Examples

Illustrative examples of the technologies disclosed herein are provided below. An embodiment of the technologies may include any one or more, and any combination of, the examples described below.

Example 1 includes an apparatus comprising a circuit board, the circuit board comprising a plurality of contact pads, wherein individual contact pads of the plurality of contact pads have a first side and a second side, wherein the first side of individual contact pads of the plurality of contact pads is gold-plated; and a plurality of solder joints, wherein individual solder joints of the plurality of solder joints join the second side of individual contact pads of the plurality of contact pads to the circuit board.

Example 2 includes the subject matter of Example 1, and further including a socket for an integrated circuit component mated with the plurality of contact pads, wherein the socket is pressure mounted to the circuit board.

Example 3 includes the subject matter of any of Examples 1 and 2, and further including the integrated circuit component, wherein the integrated circuit component is mated with the socket.

Example 4 includes the subject matter of any of Examples 1-3, and wherein individual contact pads of the plurality of contact pads comprise a copper layer adjacent a gold plate layer, wherein the copper layer is plated with nickel.

Example 5 includes the subject matter of any of Examples 1-4, and wherein individual contact pads of the plurality of contact pads comprise a tin layer, wherein the tin layer of individual contact pads of the plurality of contact pads are adjacent a solder joint of the plurality of solder joints.

Example 6 includes the subject matter of any of Examples 1-5, and wherein individual contact pads of the plurality of contact pads are raised 10-100 micrometers above a surface of the circuit board.

Example 7 includes the subject matter of any of Examples 1-6, and wherein the plurality of contact pads comprises at least 2,000 contact pads.

Example 8 includes an apparatus comprising a substrate, the substrate having a first side and a second side; a first plurality of contact pads on the first side of the substrate; a second plurality of contact pads on the second side of the substrate; and a plurality of vias defined in the substrate, wherein individual vias of the plurality of vias extend from individual contact pads of the first plurality of contact pads to individual contact pads of the second plurality of contact pads.

Example 9 includes the subject matter of Example 8, and further including a circuit board; and a plurality of solder joints, wherein individual solder joints of the plurality of solder joints join individual contact pads of the second plurality of contact pads to the circuit board.

Example 10 includes the subject matter of any of Examples 8 and 9, and wherein an area of individual contact pads of the first plurality of contact pads is larger than an area of individual contact pads of the second plurality of contact pads, further comprising, on an outer layer of the circuit board, one or more traces between at least two of the plurality of solder joints.

Example 11 includes the subject matter of any of Examples 8-10, and further including an integrated circuit component, wherein the integrated circuit component is electrically coupled to the circuit board through the first plurality of contact pads.

Example 12 includes the subject matter of any of Examples 8-11, and further including a socket for an integrated circuit component mated with the first plurality of contact pads, wherein the socket is pressure mounted to the circuit board.

Example 13 includes the subject matter of any of Examples 8-12, and further including the integrated circuit component, wherein the integrated circuit component is mated with the socket.

Example 14 includes the subject matter of any of Examples 8-13, and wherein individual contact pads of the first plurality of contact pads are raised less than 200 micrometers above a surface of the circuit board.

Example 15 includes the subject matter of any of Examples 8-14, and wherein individual contact pads of the first plurality of contact pads are gold-plated.

Example 16 includes the subject matter of any of Examples 8-15, and wherein the substrate is flexible, and wherein the substrate has a thickness less than 200 micrometers.

Example 17 includes the subject matter of any of Examples 8-16, and wherein individual contact pads of the first plurality of contact pads comprise a copper layer adjacent a gold plate layer, wherein the copper layer is plated with nickel.

Example 18 includes the subject matter of any of Examples 8-17, and wherein individual contact pads of the second plurality of contact pads comprise a tin layer.

Example 19 includes the subject matter of any of Examples 8-18, and wherein the first plurality of contact pads comprises at least 2,000 contact pads.

Example 20 includes a method comprising creating a plurality of contact pads on a circuit board, wherein individual contact pads of the plurality of contact pads are gold-plated, wherein creating the plurality of contact pads on the circuit board comprises creating the plurality of contact pads on a substrate; and joining the plurality of contact pads to the circuit board using a plurality of solder joints.

Example 21 includes the subject matter of Example 20, and further including removing the substrate from the plurality of contact pads to expose a gold-plated surface of individual contact pads of the plurality of contact pads.

Example 22 includes the subject matter of any of Examples 20 and 21, and wherein creating the plurality of contact pads on the substrate comprises creating the plurality of contact pads on a first surface of the substrate, the method further comprising creating a second plurality of contact pads on a second surface of the substrate; and creating a plurality of vias in the substrate, wherein individual vias of the plurality of vias extend from individual contact pads of the plurality of contact pads to individual contact pads of the second plurality of contact pads.

Example 23 includes the subject matter of any of Examples 20-22, and wherein an area of individual contact pads of the plurality of contact pads is larger than an area of individual contact pads of the second plurality of contact pads, further comprising patterning, on an outer layer of the circuit board, one or more traces between at least two of the plurality of solder joints.

Example 24 includes the subject matter of any of Examples 20-23, and further including mating an integrated circuit component to the circuit board to electrically couple the integrated circuit component to the circuit board through the plurality of contact pads.

Example 25 includes the subject matter of any of Examples 20-24, and further including mating a socket for an integrated circuit component mated with the plurality of contact pads using pressure mounting.

Example 26 includes the subject matter of any of Examples 20-25, and further including mating the integrated circuit component to the socket using pressure mounting.

Example 27 includes the subject matter of any of Examples 20-26, and wherein individual contact pads of the first plurality of contact pads are raised less than 200 micrometers above a surface of the circuit board.

Example 28 includes the subject matter of any of Examples 20-27, and wherein the substrate is flexible, and wherein the substrate has a thickness less than 200 micrometers.

Example 29 includes the subject matter of any of Examples 20-28, and wherein individual contact pads of the plurality of contact pads comprise a copper layer adjacent a gold plate layer, wherein the copper layer is plated with nickel.

Example 30 includes the subject matter of any of Examples 20-29, and wherein the plurality of contact pads comprises at least 2,000 contact pads.

1. An apparatus comprising:
a circuit board, the circuit board comprising:
a plurality of contact pads, wherein individual contact pads of the plurality of contact pads have a first side and a second side, wherein the first side of individual contact pads of the plurality of contact pads is gold-plated; and
a plurality of solder joints, wherein individual solder joints of the plurality of solder joints join the second side of individual contact pads of the plurality of contact pads to the circuit board.

2. The apparatus of claim 1, further comprising a socket for an integrated circuit component mated with the plurality of contact pads, wherein the socket is pressure mounted to the circuit board.

3. The apparatus of claim 2, further comprising the integrated circuit component, wherein the integrated circuit component is mated with the socket.

4. The apparatus of claim 1, wherein individual contact pads of the plurality of contact pads comprise a copper layer adjacent a gold plate layer, wherein the copper layer is plated with nickel.

5. The apparatus of claim 4, wherein individual contact pads of the plurality of contact pads comprise a tin layer, wherein the tin layer of individual contact pads of the plurality of contact pads are adjacent a solder joint of the plurality of solder joints.

6. The apparatus of claim 1, wherein individual contact pads of the plurality of contact pads are raised 10-100 micrometers above a surface of the circuit board.

7. The apparatus of claim 1, wherein the plurality of contact pads comprises at least 2,000 contact pads.

8. An apparatus comprising:
a substrate, the substrate having a first side and a second side;
a first plurality of contact pads on the first side of the substrate;
a second plurality of contact pads on the second side of the substrate; and
a plurality of vias defined in the substrate, wherein individual vias of the plurality of vias extend from individual contact pads of the first plurality of contact pads to individual contact pads of the second plurality of contact pads.

9. The apparatus of claim 8, further comprising:
a circuit board; and
a plurality of solder joints, wherein individual solder joints of the plurality of solder joints join individual contact pads of the second plurality of contact pads to the circuit board.

10. The apparatus of claim 9, wherein an area of individual contact pads of the first plurality of contact pads is larger than an area of individual contact pads of the second plurality of contact pads,
further comprising, on an outer layer of the circuit board, one or more traces between at least two of the plurality of solder joints.

11. The apparatus of claim 9, further comprising an integrated circuit component, wherein the integrated circuit component is electrically coupled to the circuit board through the first plurality of contact pads.

12. The apparatus of claim 9, further comprising a socket for an integrated circuit component mated with the first plurality of contact pads, wherein the socket is pressure mounted to the circuit board.

13. The apparatus of claim 12, further comprising the integrated circuit component, wherein the integrated circuit component is mated with the socket.

14. The apparatus of claim 9, wherein individual contact pads of the first plurality of contact pads are raised less than 200 micrometers above a surface of the circuit board.

15. The apparatus of claim 8, wherein individual contact pads of the first plurality of contact pads are gold-plated.

16. The apparatus of claim 8, wherein the substrate is flexible, and wherein the substrate has a thickness less than 200 micrometers.

17. The apparatus of claim 8, wherein the first plurality of contact pads comprises at least 2,000 contact pads.

18. A method comprising:
creating a plurality of contact pads on a circuit board, wherein individual contact pads of the plurality of contact pads are gold-plated, wherein creating the plurality of contact pads on the circuit board comprises:
creating the plurality of contact pads on a substrate; and
joining the plurality of contact pads to the circuit board using a plurality of solder joints.

19. The method of claim 18, further comprising removing the substrate from the plurality of contact pads to expose a gold-plated surface of individual contact pads of the plurality of contact pads.

20. The method of claim 18, wherein creating the plurality of contact pads on the substrate comprises creating the plurality of contact pads on a first surface of the substrate, the method further comprising:
creating a second plurality of contact pads on a second surface of the substrate; and
creating a plurality of vias in the substrate, wherein individual vias of the plurality of vias extend from individual contact pads of the plurality of contact pads to individual contact pads of the second plurality of contact pads.

21. The method of claim 20, wherein an area of individual contact pads of the plurality of contact pads is larger than an area of individual contact pads of the second plurality of contact pads,
further comprising patterning, on an outer layer of the circuit board, one or more traces between at least two of the plurality of solder joints.

22. The method of claim 18, further comprising mating an integrated circuit component to the circuit board to electrically couple the integrated circuit component to the circuit board through the plurality of contact pads.

23. The method of claim 18, further comprising mating a socket for an integrated circuit component mated with the plurality of contact pads using pressure mounting.

24. The method of claim 23, further comprising mating the integrated circuit component to the socket using pressure mounting.

25. The method of claim 18, wherein individual contact pads of the first plurality of contact pads are raised less than 200 micrometers above a surface of the circuit board.
